(19) United States
(12) Patent Application Publication
(10) Pub. No.: US 2014/0251432 A1
(43) Pub. Date: Sep. 11, 2014

(54) ADHESIVE FOR SOLAR BATTERY BACK SHEETS

(71) Applicant: Henkel AG & Co. KGaA, Duesseldorf (DE)

(72) Inventor: Shoko Ito, Osaka (JP)

(21) Appl. No.: 14/286,025

(22) Filed: May 23, 2014

Related U.S. Application Data
(63) Continuation of application No. PCT/JP2012/080799, filed on Nov. 21, 2012.

(30) Foreign Application Priority Data
Nov. 25, 2011 (JP) 2011-257268

(51) Int. Cl. H01L 31/048; C09J 175/14

(52) U.S. Cl. CPC H01L 31/0487; C09J 175/14
USPC 136/259; 136/252; 525/450

(57) ABSTRACT

An object of the present invention is to provide a urethane adhesive for solar battery back sheets, which has satisfactory initial adhesion to a film in the production of a solar battery back sheet, satisfactory initial adhesive property after curing and high adhesive property at high temperature, and also has a sufficient hydrolysis resistance over the long term and is excellent in overall balance; a solar battery back sheet which is obtainable by using the adhesive; and a solar battery module. Disclosed is an adhesive for solar battery back sheets, including a urethane resin obtainable by the reaction of an acrylic polyol with an isocyanate compound, wherein the acrylic polyol is obtainable by polymerizing polymerizable monomers, the polymerizable monomers include a monomer having a hydroxyl group and other monomers, the monomer having a hydroxyl group includes a hydroxyalkyl (meth)acrylate, and the other monomers include acrylonitrile and (meth)acrylic ester(s).

### CROSS-REFERENCE TO RELATED APPLICATION

This application claims benefit under Paris Convention of Japanese Patent Application No. 2011-257268 filed on Nov. 25, 2011, incorporated herein by reference in its entity.

### TECHNICAL FIELD

The present invention relates to an adhesive for solar battery back sheets. More particularly, the present invention relates to a solar battery back sheet obtainable by using the adhesive, and a solar battery module obtainable by using the solar battery back sheet.

### BACKGROUND ART

Practical use of a solar battery as useful energy resources makes progress. The solar battery includes various types, and a silicon-based solar battery, an inorganic compound-based solar battery, an organic solar battery and the like are known as a typical solar battery.

In these solar batteries, a surface protective sheet is commonly provided on a surface on which sunlight falls, for the purpose of protecting the surface. A back side protective sheet (back sheet) is also provided on a surface opposite to the surface on which sunlight falls, for the purpose of protecting a solar battery cell, and it is required for the back sheet to have various excellent physical properties such as weatherability, water resistance, heat resistance, moisture barrier properties and gas barrier properties so as to suppress long-term performance deterioration of the solar battery to the minimum extent.

In order to obtain a sheet having these various physical properties, various films are used, and examples thereof include metal foils, metal plates and metal deposited films, such as aluminum, copper and steel plates; plastic films such as polypropylene, polyvinyl chloride, polyester, fluorine resin and acrylic resin films; and the like.

In order to further improve performances, a laminate obtainable by laminating these films is also used as the back sheet of the solar battery.

An example of the laminate obtained by laminating the films is shown in FIG. 1. A back sheet 10 is a laminate of plural films 11 and 12, and the films 11 and 12 are laminated by interposing an adhesive 13 therebetween.

A lamination method of films is commonly a dry lamination method, and it is required for the adhesive 13 to have sufficient adhesive property to the films 11 and 12.

The back sheet 10 constitutes a solar battery module 1, together with a sealing material 20, a solar battery cell 30, and a glass plate 40 (see FIG. 3).

Since the solar battery module 1 is exposed outdoors over the long term, sufficient durability against high temperature, high humidity and sunlight is required. Particularly, when the adhesive 13 has low performances, the films 11 and 12 are peeled and thus appearance of the laminated back sheet 10 is impaired. Therefore, it is required that the adhesive for solar battery back sheets does not undergo peeling of the film even when exposed over the long term.

The adhesive for solar battery back sheets includes a urethane adhesive as an example. Patent Documents 1 to 3 disclose that an adhesive for solar battery back sheets, in which a curing agent such as isocyanate is blended in acrylic polyol for the purpose of improving durability and hydrolysis resistance, is used for the production of a solar battery back sheet.

Patent Document 1 and 2 disclose that an adhesive is produced by blending an isocyanate curing agent in an acrylic polyol (see Patent Document 1, Tables 1 and 2, Patent Document 2, Tables 1 and 2) and a solar battery back sheet having excellent long-term weatherability and hydrolysis resistance is produced by using this adhesive.

Patent Document 3 discloses that a solar battery back sheet having a satisfactory initial adhesive property and a long-term durability is produced by using a specific acrylic polyol as raw materials of the adhesive.

However, durability required for the adhesive for solar battery back sheets increases year by year, and a higher adhesive property is required for the adhesive for back sheets. Since a solar battery module is mainly used outdoors, a high adhesive property at high temperature is desired.

Therefore, it is important that the adhesive for solar battery back sheets has not only sufficient hydrolysis resistance, but also a higher adhesive property to a film base material and sufficient adhesive property even at high temperature, and the adhesives of Patent Documents 1 to 3 do not necessarily satisfy the above-mentioned performances. When the solar battery back sheet is produced by using the adhesives of Patent Documents 1 to 3, plural films constituting the back sheet may be mutually peeled in a severe outdoor environment.

The solar battery back sheet is commonly produced by applying an adhesive having an appropriate viscosity to a film, drying the adhesive, laminating films (dry lamination method), and then curing the obtainable laminate for several days. Therefore, it is also required for the adhesive for solar battery back sheets to be excellent in solution viscosity suited for coating, and initial adhesion to the film at the time of lamination.
Patent Document 1: JP2010-263193A
Patent Document 2: JP2010-238815A
Patent Document 3: JP2011-105819A

### DISCLOSURE OF THE INVENTION

### Problems to be Solved by the Invention

The present invention has been made so as to solve such a problem and an object thereof is to provide a urethane adhesive for solar battery back sheets, which has a satisfactory initial adhesion to a film at the time of the production of a solar battery back sheet, a satisfactory initial adhesive property after curing (or aging) and high adhesive property at high temperature, and also has sufficient hydrolysis resistance over the long term and is excellent in overall balance; a solar battery back sheet obtainable by using the adhesive; and a solar battery module obtainable by using the solar battery back sheet.

### Means for Solving the Problems

The present inventors have intensively studied and found, surprisingly, that it is possible to obtain an adhesive for solar battery back sheets, which has improved initial adhesion to a film and improved initial adhesive property after curing, and is also excellent in long-term hydrolysis resistance and overall balance, by using a specific acrylic polyol as a raw material of a urethane resin, and thus the present invention has been completed.

Namely, the present invention provides, in an aspect, an adhesive for solar battery back sheets, including a urethane resin obtainable by the reaction of an acrylic polyol with an isocyanate compound, wherein the acrylic polyol is obtainable by polymerizing polymerizable monomers, the polymerizable monomers comprise a monomer having a hydroxyl group and other monomers, the monomer having a hydroxyl group comprises a hydroxyalkyl (meth)acrylate, and the other monomers comprise acrylonitrile and (meth)acrylic ester(s).

The present invention provides, in an embodiment, the above adhesive for solar battery back sheets, wherein the content of the acrylonitrile is 1 to 40 parts by weight based on 100 parts by weight of the polymerizable monomers.

The present invention provides, in another embodiment, the above adhesive for solar battery back sheets, wherein the acrylic polyol has a glass transition temperature of 20° C. or lower.

The present invention provides, in a preferred embodiment, the above adhesive for solar battery back sheet, wherein the acrylic polyol has a hydroxyl value of 0.5 to 45 mgKOH/g.

The present invention provides, in another aspect, a solar battery back sheet obtainable by using the above adhesive for solar battery back sheets.

The present invention provides, in a preferred aspect, a solar battery module obtainable by using the above solar battery back sheet.

### Effects of the Invention

The adhesive for solar battery back sheets according to the present invention includes a urethane resin obtainable by the reaction of an acrylic polyol with an isocyanate compound, and the acrylic polyol is obtainable by polymerizing polymerizable monomers, the polymerizable monomers comprise a monomer having a hydroxyl group and other monomers, the monomer having a hydroxyl group comprises a hydroxyalkyl (meth)acrylate, and the other monomers comprise acrylonitrile and (meth)acrylic ester(s).

Whereby, the adhesive for solar battery back sheets has sufficient initial adhesion to a film while maintaining excellent hydrolysis resistance, and also has improved initial adhesive property after curing (or aging) and improved adhesive property at high temperature and is excellent in overall balance.

When the content of the acrylonitrile is 1 to 40 parts by weight based on 100 parts by weight of the polymerizable monomers, it is possible to obtain an adhesive for solar battery back sheets, which has an appropriate solution viscosity at the time of the production of a back sheet, and has further improved initial adhesion to a film.

With regard to an adhesive for solar battery back sheets of the present invention, when the acrylic polyol has a glass transition temperature of 20° C. or lower, the initial adhesion to a film and the initial adhesive property after curing are further improved, whereby, the adhesive becomes a more preferred adhesive.

With regard to an adhesive for solar battery back sheets of the present invention, when the acrylic polyol has a hydroxyl value of 0.5 to 45 mgKOH/g, hydrolysis resistance and adhesive property at high temperature are remarkably improved, and the adhesive is more preferable.

Since a solar battery back sheet is obtainable by using the above adhesive for solar battery back sheet, it is more excellent in productivity and can prevent a film from peeling from the adhesive under long-term outdoor exposure from an initial stage of lamination.

Since a solar battery module according to the present invention is obtainable by using the above solar battery back sheet, it is excellent in productivity and is less likely to cause poor appearance, and is also excellent in durability.

### BRIEF DESCRIPTION OF THE DRAWINGS

FIG. 1 is a sectional view showing an embodiment of a solar battery back sheet according to the present invention.

FIG. 2 is a sectional view showing another embodiment of a solar battery back sheet according to the present invention.

FIG. 3 is a sectional view showing an embodiment of a solar battery module according to the present invention.

### MODE FOR CARRYING OUT THE INVENTION

The adhesive for solar battery back sheets according to the present invention includes a urethane resin obtainable by the reaction of an acrylic polyol with an isocyanate compound.

The urethane resin according to the present invention is a polymer obtainable by the reaction of an acrylic polyol with an isocyanate compound, and has a urethane bond. A hydroxyl group of the acrylic polyol reacts with an isocyanate group. The acrylic polyol is obtainable by the addition polymerization of polymerizable monomers, and the polymerizable monomers include a “monomer having a hydroxyl group” and “other monomers”.

The “monomer having a hydroxyl group” includes hydroxyalkyl (meth)acrylate, and the hydroxyalkyl (meth)acrylate may be used alone or two or more kinds of the hydroxyalkyl (meth)acrylates may be used in combination. The hydroxyalkyl (meth)acrylate may also be used in combination with a monomer having a hydroxyl group, other than the hydroxyalkyl (meth)acrylate.

Examples of the “hydroxyalkyl (meth)acrylate” include, but are not limited to, 2-hydroxyethyl (meth)acrylate, 2-hydroxypropyl (meth)acrylate, 3-hydroxypropyl (meth)acrylate, 4-hydroxybutyl acrylate and the like.

Examples of the “polymerizable monomer having a hydroxyl group, other than the hydroxylalkyl (meth)acrylate” include polyethylene glycol mono(meth)acrylate, polypropylene glycol mono(meth)acrylate and the like.

The “other monomers” are “radical polymerizable monomers having an ethylenic double bond” other than the monomer having a hydroxyl group. The other monomers may be only acrylonitrile and (meth)acrylic ester in the acrylic polyol, or may further include radical polymerizable monomers having an ethylenic double bond, other than acrylonitrile and (meth)acrylic ester.

The “(meth)acrylic ester” is a compound obtainable by the condensation reaction of (meth)acrylic acid with a monoalcohol, and has an ester bond. Specific examples thereof include methyl (meth)acrylate, ethyl (meth)acrylate, butyl (meth)acrylate, cyclohexyl (meth)acrylate, 2-ethylhexyl (meth)acrylate, dicyclopentanyl (meth)acrylate, glycidyl (meth)acrylate, isobornyl (meth)acrylate and the like. In the present invention, it is preferred to include at least one kind selected from methyl (meth)acrylate, ethyl (meth)acrylate, butyl (meth)acrylate, cyclohexyl (meth)acrylate and 2-ethylhexyl (meth)acrylate, and it is more preferred to include at least one kind selected from methyl (meth)acrylate, ethyl (meth)acrylate and butyl (meth)acrylate.

Examples of the “radical polymerizable monomers having an ethylenic double bond, other than acrylonitrile and (meth)acrylic ester” include, but are not limited to, (meth)acrylic acid, styrene, vinyltoluene and the like.

The “acrylonitrile” is a compound represented by the general formula: CH₂═CH—CN, and is also called acrylic nitrile, acrylic acid nitrile or vinyl cyanide.

The content of the acrylonitrile in the polymerizable monomers is preferably 1 to 40 parts by weight, more preferably 5 to 35 parts by weight, and particularly preferably 5 to 25 parts by weight, based on 100 parts by weight of the polymerizable monomers. When the content of the acrylonitrile is within the above range, it is possible to obtain an adhesive for solar battery back sheet, which is excellent in balance among coatability, initial adhesive property to a film after curing, and adhesive property at high temperature.

In the present description, an acrylic acid and a methacrylic acid are collectively referred to as a “(meth)acrylic acid”, and “an acrylic ester and a methacrylic ester” are collectively referred to as a “(meth)acrylic ester” or a “(meth)acrylate”.

As long as the objective adhesive for solar battery back sheets of the present invention can be obtained, there is no particular limitation on the polymerization method of the polymerizable monomers. For example, the above-mentioned polymerizable monomers can be polymerized by radically polymerizing by using a conventional solution polymerization method in an organic solvent in the presence of an appropriate catalyst. Herein, the “organic solvent” can be used so as to polymerize the polymerizable monomers and there is no particular limitation on the organic solvent as long as it does not substantially exert an adverse influence on characteristics as an adhesive for solar battery back sheets after the polymerization reaction. Examples of such a solvent include aromatic-based solvents such as toluene and xylene; alcohol-based solvents such as isopropyl alcohol and n-butyl alcohol; ester-based solvents such as ethyl acetate and butyl acetate; and combinations thereof.

The polymerization reaction conditions such as reaction temperature, reaction time, kind of organic solvents, kind and concentration of monomers, stirring rate, as well as kind and concentration of catalysts in the polymerization of the polymerizable monomers can be appropriately selected according to characteristics of the objective adhesive.

The “catalyst” is preferably a compound which can accelerate the polymerization of the polymerizable monomers by the addition in a small amount and can be used in an organic solvent. Examples of the catalyst include anmonium persulfate, sodium persulfate, potassium persulfate, t-butyl peroxybenzoate, 2,2-azobisisobutyronitrile (AIBN), 2,2-azobis(2-aminodipropane)dihydrochloride and 2,2-azobis(2,4-dimethylvarelonitrile), and 2,2-azobisisobutyronitrile (AIBN) is particularly preferable.

A chain transfer agent can be appropriately used for the polymerization in the present invention so as to adjust the molecular weight. It is possible to use, as the “chain transfer agent”, compounds well-known to those skilled in the art. Examples thereof include mercaptans such as n-dodecylmercaptan (nDM), laurylmethylmercaptan and mercaptoethanol.

As mentioned above, the acrylic polyol is obtainable by polymerizing the polymerizable monomers. From the viewpoint of coatability of the adhesive, the weight average molecular weight of the acrylic polyol is preferably 200,000 or less, and more preferably 5,000 to 100,000. The weight average molecular weight is a value measured by gel permeation chromatography (GPC) in terms of polystyrene standard. Specifically, the value can be measured using the following GPO apparatus and measuring method. HCL-8220GPC manufactured by TOSOH CORPORATION is used as a GPC apparatus, and RI is used as a detector. Two TSK gel SuperMultipore HZ-M manufactured by TOSOH CORPORATION are used as a GPC column. A sample is dissolved in tetrahydrofuran and the obtained solution is allowed to flow at a flow rate of 0.35 ml/minute and a column temperature of 40° C., and then Mw is determined by conversion of molecular weight based on a calibration curve which is obtained by using polystyrene having a monodisperse molecular weight as a standard reference material.

A glass transition temperature of the acrylic polyol can be set by adjusting a mass fraction of a monomer to be used. The glass transition temperature of the acrylic polyol can be determined based on a glass transition temperature of a homopolymer obtainable from each monomer and a mass fraction of the homopolymer used in the acrylic polyol using the following calculation formula (i). It is preferred to determine a composition of the monomer using the glass transition temperature determined by the calculation:

1/Tg=W1/Tg1+W2/Tg2+ . . . +Wn/Tgn (i):

where Tg in the above formula (i) denotes the glass transition temperature of the acrylic polyol, each of W1, W2, . . . , Wn denotes a mass fraction of each monomer, and each of Tg1, Tg2, . . . , and Tgn denotes a glass transition temperature of a homopolymer of corresponding each monomer.

A value disclosed in the document can be used as Tg of the homopolymer. It is possible to refer, as such a document, for example, the following documents: Acrylic Ester Catalog of Mitsubishi Rayon Co., Ltd. (1997 Version); edited by Kyozo Kitaoka, “Shin Kobunshi Bunko 7, Guide to Synthetic Resin for Coating Material”, Kobunshi Kankokai, published in 1997, pp. 168-169; and “POLYMER HANDBOOK”, 3rd Edition, pp. 209-277, John Wiley & Sons, Inc. published in 1989.

In the present specification, glass transition temperatures of homopolymers of the following monomers are as follows.

Methyl methacrylate: 105° C.
n-Butyl acrylate: −54° C.
Ethyl acrylate: −20° C.
2-Hydroxyethyl methacrylate: 55° C.
2-Hydroxyethyl acrylate: −15° C.
Glycidyl methacrylate: 41° C.

### Acrylonitrile: 130° C.

### Styrene: 105° C.

In the present invention, the glass transition temperature of the acrylic polyol is preferably 20° C. or lower, more preferably −55° C. to 10° C., and particularly preferably −30° C. to 0° C., from the viewpoint of initial adhesion to a film at the time of lamination.

A hydroxyl value of the acrylic polyol is preferably 0.5 to 45 mgKOH/g, more preferably 1 to 40 mgKOH/g, and particularly preferably 5 to 35 mgKOH/g. When the hydroxyl value of the acrylic polyol is within the above range, it is possible to obtain an adhesive for solar battery back sheet, which is excellent in initial adhesive property after curing, adhesive property at high temperature, and hydrolysis resistance.

In the present description, the hydroxyl value is a number of mg of potassium hydroxide required to neutralize acetic acid combined with hydroxyl groups when 1 g of a resin is acetylated.

In the present invention, the hydroxyl value is specifically calculated by the following formula (ii).

Hydroxyl value=[(weight of (meth)acrylate having a hydroxyl group)/(molecular weight of (meth)acrylate having a hydroxyl group)]×(mole number of hydroxyl groups contained in 1 mol of (meth)acrylate monomer having a hydroxyl group)×[(formula weight of KOH×1,000)/(weight of the acrylic polyol)] (ii):

Examples of the isocyanate compound include an aliphatic isocyanate, an alicyclic isocyanate and an aromatic isocyanate, and there is no particular limitation on the isocyanate compound as long as the objective adhesive for solar battery back sheets of the present invention can be obtained.

In the present specification, the “aliphatic isocyanate” refers to a compound which has a chain-like hydrocarbon chain in which isocyanate groups are directly combined to the hydrocarbon chain, and also has no cyclic hydrocarbon chain. Although the “aliphatic isocyanate” may have an aromatic ring, the aromatic ring is not directly combined with the isocyanate groups.

In the present specification, the aromatic ring is not included in the cyclic hydrocarbon chain.

The “alicyclic isocyanate” is a compound which has acyclic hydrocarbon chain and may have a chain-like hydrocarbon chain. The isocyanate group may be either directly combined with the cyclic hydrocarbon chain, or may be directly combined with the chain-like hydrocarbon chain which may be present. Although the “alicyclic isocyanate” may include an aromatic ring, the aromatic ring is not directly combined to the isocyanate groups.

The “aromatic isocyanate” refers to a compound which has an aromatic ring, in which isocyanate groups are directly combined with the aromatic ring. Therefore, a compound, in which isocyanate groups are not directly combined with the aromatic ring, is classified into the aliphatic isocyanate or the alicyclic isocyanate even if it includes the aromatic ring in the molecule.

Therefore, for example, 4,4′-diphenylmethane diisocyanate (OCN—C₆H₄—CH₂—C₆H₄—NCO) corresponds to the aromatic isocyanate, since the isocyanate groups are directly combined with the aromatic ring. On the other hand, for example, xylylene diisocyanate (OCN—CH₂—C₆H₄—CH₂—NCO) corresponds to the aliphatic isocyanate since it includes an aromatic ring, but the isocyanate groups are not directly combined with the aromatic ring and combined with methylene groups.

The aromatic ring may be fused with two or more benzene rings.

Examples of the aliphatic isocyanate include 1,4-diisocyanatobutane, 1,5-diisocyanatopentane, 1,6-diisocyanatohexane (hereinafter also referred to as HDI), 1,6-diisocyanato-2,2,4-trimethylhexane, 2,6-diisocyanatohexanoic acid methyl ester (lysine diisocyanate), 1,3-bis(isocyanatomethyl)benzene (xylylene diisocyanate) and the like.

Examples of the alicyclic isocyanate include 5-isocyanato-1-isocyanatomethyl-1,3,3-trimethylcyclohexane (isophorone diisocyanate), 1,3-bis(isocyanatomethyl)cyclohexane (hydrogenated xylylene diisocyanate), bis(4-isocyanatocyclohexyl)methane (hydrogenated diphenylmethane diisocyanate), 1,4-diisocyanatocyclohexane and the like.

Examples of the aromatic isocyanate include, 4,4′-diphenylmethane diisocyanate, p-phenylene diisocyanate, m-phenylene diisocyanate and the like. These isocyanate compounds can be used alone, or in combination.

In the present invention, there is no particular limitation on the isocyanate compound as long as the objective urethane adhesive according to the present invention can be obtained. From the viewpoint of weatherability, it is preferred to select from the aliphatic and alicyclic isocyanates. Particularly, HDI, isophorone diisocyanate and xylylene diisocyanate are preferable, and a trimer of HDI is particularly preferable.

The urethane resin according to the present invention can be obtained by reacting the acrylic polyol with the isocyanate compound. In the reaction, a known method can be used and the reaction can be usually performed by mixing the acrylic polyol with the isocyanate compound. There is no particular limitation on the mixing method as long as the urethane resin according to the present invention can be obtained.

The adhesive for solar battery back sheets of the present invention may contain an ultraviolet absorber for the purpose of improving long-term weatherability. It is possible to use, as the ultraviolet absorber, a hydroxyphenyltriazine-based compound and other commercially available ultraviolet absorbers. The “hydroxyphenyltriazine-based compound” is a kind of a triazine derivative in which a hydroxyphenyl derivative is combined with a carbon atom of the triazine derivative, and examples thereof include TINUVIN 400, TINUVIN 405, TINUVIN 479, TINUVIN 477 and TINUVIN 460 (all of which are trade names) which are available from BASE Corp.

The adhesive for solar battery back sheets may further contain a hindered phenol-based compound. The “hindered phenol-based compound” is commonly referred to as a hindered phenol-based compound, and there is no particular limitation as long as the objective adhesive for solar battery back sheets according to the present invention can be obtained.

Commercially available products can be used as the hindered phenol-based compound. The hindered phenol-based compound is, for example, commercially available from BASF Corp. Examples thereof include IRGANOX1010, TRGANOX1035, IRGANOX1076, IRGANOX1135, IRGANOX1330 and IRGANOX1520 (all of which are trade names). The hindered phenol-based compound is added to the adhesive as an antioxidant and may be used, for example, in combination with a phosphite-based antioxidant, a thioether-based antioxidant, an amine-based antioxidant and the like.

The adhesive for solar battery back sheets according to the present invention may further contain a hindered amine-based compound.

The “hindered amine-based compound” is commonly referred to as a hindered amine-based compound, and there is no particular limitation as long as the objective adhesive for solar battery back sheets according to the present invention can be obtained.

Commercially available products can be used as the hindered amine-based compound. Examples of the hindered amine-based compound include TINUVIN 765, TINUVIN 111FDL, TINUVIN 123, TINUVIN 144, TINUVIN 152, TINUVIN 292 and TINUVIN 5100 (all of which are trade names) which are commercially available from BASF Corp. The hindered amine-based compound is added to the adhesive as a light stabilizer and may be used, for example, in combination with a benzotriazole-based compound, a benzoate-based compound and the like.

The adhesive for solar battery back sheets according to the present invention may further contain a silane compound.

It is possible to use, as the silane compound, for example, (meth)acryloxyalkyltrialkoxysilanes, (meth)acryloxyalkylalkylalkoxysilanes, vinyltrialkoxysilanes, vinylalkylalkoxysilanes, epoxysilanes, mercaptosilanes and isocyanuratesilanes. However, the silane compound is not limited only to these silane compounds.

Examples of the “(meth)acryloxyalkyltrialkoxysilanes” include 3-(meth)acryloxypropyltrimethoxysilane, 3-(meth)acryloxypropyltriethoxysilane, 4-(meth)acryloxyethyltrimethoxysilane and the like.

Examples of the “(meth)acryloxyalkylalkylalkoxysilanes” include 3-(meth)acryloxypropylmethyldimethoxysilane, 3-(meth)acryloxypropylmethyldiethoxysilane, 3-(meth)acryloxypropylethyldiethoxysilane, 3-(meth)acryloxyethylmethyldimethoxysilane and the like.

Examples of the “vinyltrialkoxysilanes” include vinyltrimethoxysilane, vinyltriethoxysilane, vinyldimethoxyethoxysilane, vinyltri(methoxyethoxy)silane, vinyltri(ethoxymethoxy)silane and the like.

Examples of the “vinylalkylalkoxysilanes” include vinylmethyldimethoxysilane, vinylethyldi(methoxyethoxy)silane, vinyldimethylmethoxysilane, vinyldiethyl(methoxyethoxy)silane and the like.

For example, the “epoxysilanes” can be classified into glycidyl-based silanes and epoxycyclohexyl-based silanes. The “glycidyl-based silanes” have a glycidoxy group, and specific examples thereof include 3-glycidoxypropylmethyldiisopropenoxysilane, 3-glycidoxypropyltrimethoxysilane, 3-glycidoxypropyltriethoxysilane, 3-glycidoxypropyldiethoxysilane and the like.

The “epoxycyclohexyl-based silanes” have a 3,4-epoxycyclohexyl group, and specific examples thereof include 2-(3,4-epoxycyclohexyl)ethyltrimethoxysilane, 2-(3,4-epoxycyclohexyl)ethyltriethoxysilane and the like.

Examples of the “mercaptosilanes” include 3-mercaptopropyltrimethoxysilane, 3-mercaptopropyltriethoxysilane and the like.

Examples of the “isocyanuratesilanes” include tris(3-(trimethoxysilyl)propyl) isocyanurate and the like.

The adhesive for solar battery back sheets according to the present invention can further contain other components as long as the objective adhesive for solar battery back sheets can be obtained.

There is no particular limitation on timing of the addition of the “other components” to the adhesive for solar battery back sheets as long as the objective adhesive for solar battery back sheets according to the present invention can be obtained. For example, the other components may be added, together with the acrylic polyol and the isocyanate compound, in the synthesis of the urethane resin, or may be added after synthesizing the urethane resin by reacting the acrylic polyol with the isocyanate compound.

Examples of the “other components” include a tackifier resin, a pigment, a plasticizer, a flame retardant, a catalyst, a wax and the like.

Examples of the “tackifier resin” include a styrene-based resin, a terpene-based resin, aliphatic petroleum resin, an aromatic petroleum resin, a rosin ester, an acrylic resin, a polyester resin (excluding polyesterpolyol) and the like.

Examples of the “pigment” include titanium oxide, carbon black and the like.

Examples of the “plasticizer” include dioctyl phthalate, dibutyl phthalate, diisononyl adipate, dioctyl adipate, mineral spirit and the like.

Examples of the “flame retardant” include a halogen-based flame retardant, a phosphorous-based flame retardant, an antimony-based flame retardant, a metal hydroxide-based flame retardant and the like.

Examples of the “catalyst” include metal catalysts such as tin catalysts (trimethyltin laurate, trimethyltin hydroxide, stannous octoate, dibutyltin dilaurate, dibutyltin diacetate, dibutyltin maleate, etc.), lead-based catalysts (lead oleate, lead naphthenate, lead octenoate, etc.), and other metal catalysts (naphthenic acid metal salts such as cobalt naphthenate) and amine-based catalysts such as triethylenediamine, tetramethylethylenediamine, tetramethylhexylenediamine, diazabicycloalkenes, dialkylaminoalkylamines and the like.

The “wax” is preferably wax such as a paraffin wax and a microcrystalline wax.

The viscosity of the adhesive for solar battery back sheets is measured by using a rotational viscometer (Model BM, manufactured by TOKIMEC Inc.) When solution viscosity at the solid content of 40% is 4,000 mPa·s or more, coatability of the adhesive can deteriorate. If a solvent is further added so as to decrease the viscosity, coating is performed at low solid component concentration, and thus productivity of the solar battery back sheet may deteriorate.

The adhesive for solar battery back sheets of the present invention can be produced by mixing the above-mentioned urethane resin and other components which are optionally added. There is no particular limitation on the mixing method as long as the objective adhesive for solar battery back sheets of the present invention can be obtained. There is also no particular limitation on the order of mixing the components. The adhesive for solar battery back sheets according to the present invention can be produced without requiring a special mixing method and a special mixing order. The obtained adhesive for solar battery back sheets has sufficient initial adhesion to a film while maintaining excellent hydrolysis resistance, and also has improved initial adhesive property after curing and improved adhesive property at high temperature and is excellent in overall balance.

It is required for an adhesive for producing a solar battery module to have an adhesive property and a hydrolysis resistance in a particularly high level. The adhesive for solar battery back sheets of the present invention is excellent in initial adhesion to a film and adhesive property to a film at high temperature, and also has satisfactory initial adhesive property after curing and excellent hydrolysis resistance, and thus the adhesive is suitable as an adhesive for solar battery back sheet.

In the case of producing a solar battery back sheet, the adhesive of the present invention is applied to a film. The application can be performed by various methods such as gravure coating, wire bar coating, air knife coating, die coating, lip coating and comma coating methods. Plural films coated with the urethane adhesive for solar battery back sheets of the present invention are laminated with each other to obtain a solar battery back sheet.

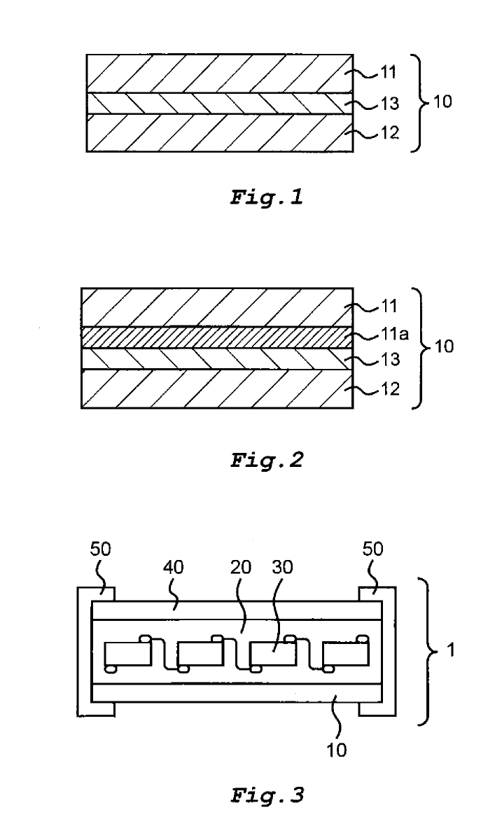

Embodiments of the solar battery back sheet of the present invention are shown in FIGS. 1 to 3, but the present invention is not limited to these embodiments.

FIG. 1 is a sectional view of a solar battery back sheet of the present invention. The solar battery back sheet 10 is formed of two films and an adhesive for solar battery back sheet 13 interposed therebetween, and the two films 11 and 12 are laminated each other by the adhesive for solar battery back sheets 13. The films 11 and 12 may be made of either the same or different material. In FIG. 1, the two films 11 and 12 are laminated each other, or three or more films may be laminated one another.

Another embodiment of the solar battery back sheet according to the present invention is shown in FIG. 2. In FIG. 2, a thin film 11a is formed between the film 11 and the adhesive for solar battery back sheet 13. For example, the drawing shows an embodiment in which a metal thin film 11a is formed on the surface of the film 11 when the film 11 is a plastic film. The metal thin film 11a can be formed on the surface of the plastic film 11 by vapor deposition, and the solar battery back sheet of FIG. 2 can be obtained by laminating the metal thin film 11, on which surface the metal thin film 11a is formed, with the film 12 by interposing the adhesive for solar battery back sheet 13 therebetween.

Examples of the metal to be deposited on the plastic film include aluminum, steel, copper and the like. It is possible to impart barrier properties to the plastic film by subjecting the film to vapor deposition. Silicon oxide or aluminum oxide is used as a vapor deposition material. The plastic film 11 as a base material may be either transparent, or white- or black-colored.

A plastic film made of polyvinyl chloride, polyester, a fluorine resin or an acrylic resin is used as the film 12. In order to impart heat resistance, weatherability, rigidity, insulating properties and the like, a polyethylene terephthalate film or a polybutylene terephthalate film is preferably used. The films 11 and 12 may be either transparent, or may be colored.

The deposited thin film 11a of the film 11 and the film 12 are laminated each other using the adhesive for solar battery back sheets 13 according to the present invention, and the films 11 and 12 are often laminated each other by a dry lamination method. Therefore, it is required for the adhesive for solar battery back sheets 13 to have excellent initial adhesion to a film at the time of lamination and excellent initial adhesive property to a film after curing.

FIG. 3 shows a sectional view of an example of a solar battery module of the present invention. In FIG. 3, it is possible to obtain a solar battery module 1 by laying a glass plate 40, a sealing material 20 such as an ethylene-vinyl acetate resin (EVA), plural solar battery cells 30 which are commonly connected each other to generate a desired voltage, and a back sheet 10 one another, and then fixing these members 10, 20, 30 and 40 using a spacer 50.

As mentioned above, since the back sheet 10 is a laminate of the plural films 11 and 12, it is required for the urethane adhesive 13 to cause no peeling of the films 11 and 12 even when the back sheet 10 is exposed outdoors over the long term, and to be excellent in hydrolysis resistance and adhesive property at high temperature.

Main embodiments of the present invention will be shown below.

1. An adhesive for solar battery back sheets, including a urethane resin obtainable by the reaction of an acrylic polyol with an isocyanate compound, wherein

the acrylic polyol is obtainable by polymerizing polymerizable monomers,

the polymerizable monomers include a monomer having a hydroxyl group and other monomers,

the monomer having a hydroxyl group includes a hydroxyalkyl (meth)acrylate, and

the other monomers include acrylonitrile and (meth)acrylic ester(s).

2. The above adhesive for solar battery back sheets, wherein the content of the acrylonitrile is 1 to 40 parts by weight based on 100 parts by weight of the polymerizable monomers.
3. The above adhesive for solar battery back sheets, wherein the acrylic polyol has a glass transition temperature of 20° C. or lower.
4. The above adhesive for solar battery back sheet, wherein the acrylic polyol has a hydroxyl value of 0.5 to 45 mgKOH/g.
5. A solar battery back sheet obtainable by using the adhesive for solar battery back sheets according to any one of the above 1 to 4.
6. A solar battery module obtainable by using the solar battery back sheet according to the above 5.

### EXAMPLES

The present invention will be described below by way of Examples and Comparative Examples, and these Examples are merely for illustrative purposes and are not meant to be limiting on the present invention.

### Synthesis of Acrylic Polyol

### Synthetic Example 1 (Acrylic polyol (Polymer 1))

In a four-necked flask equipped with a stirring blade, a thermometer and a reflux condenser tube, 150 g of ethyl acetate (manufactured by Wako Pure Chemical Industries, Ltd.) was charged and refluxed at about 80° C. In the flask, 1 g of 2,2-azobisisobutyronitrile as a polymerization initiator was added and a mixture of monomers in each amount shown in Table 1 was continuously added dropwise over 1 hour and 30 minutes. After heating for 2 hours, a solution of an acrylic polyol having a non-volatile content (solid content) of 40.0% by weight was obtained.

The composition of the polymerizable monomer component of the acrylic polyol (polymer 1) and physical properties of the obtained polymer 1 are shown in Table 1.

### Synthetic Examples 2 to 15

In the same manner as in Synthetic Example 1, except that the composition of monomers used in the synthesis of the acrylic polyol in Synthetic Example 1 was changed as shown in Table 1 and Table 2, acrylic polyols (polymer 2 to polymer 14) and an acrylic polymer (polymer 15) were obtained. Physical properties of the obtained polymers 2 to 15 are shown in Table 1 and Table 2.

The polymerizable monomers shown in Table 1 and Table 2, and other components are shown below.

Methyl methacrylate (MMA): manufactured by Wako Pure Chemical Industries, Ltd.
Butyl acrylate (BA): manufactured by Wako Pure Chemical Industries, Ltd.
Ethyl acrylate (EA): manufactured by Wako Pure Chemical Industries, Ltd.
Glycidyl methacrylate (GMA): manufactured by Wako Pure Chemical Industries, Ltd.
Acrylonitrile (AN): manufactured by Wako Pure Chemical Industries, Ltd.
2-Hydroxyethylmethacrylate (HEMA): manufactured by Wako Pure Chemical Industries, Ltd.
2-Hydroxyethyl acrylate (HEA): manufactured by Wako Pure Chemical Industries, Ltd.
Styrene (St): manufactured by Wako Pure Chemical Industries, Ltd. 2,2-Azobisisobutyronitrile (AIBN): manufactured by Otsuka Chemical Co., Ltd.
n-Dodecylmercaptan (nDM): manufactured by NOF CORPORATION

TABLE 1

| | Synthetic Examples | | | | | | | |
|---|---|---|---|---|---|---|---|---|
| | 1 | 2 | 3 | 4 | 5 | 6 | 7 | 8 |
| St | 0 | 2 | 3 | 2 | 2 | 3 | 3 | 10 |
| MMA | 4 | 3 | 25 | 30 | 23 | 32 | 22 | 20 |
| BA | 80 | 73 | 60 | 57 | 55 | 54 | 56 | 56 |
| EA | 0 | 0 | 0 | 0 | 0 | 0 | 0 | 0 |
| GMA | 0 | 0 | 0 | 0 | 0 | 2 | 2 | 0 |
| AN | 10 | 20 | 10 | 10 | 10 | 5 | 15 | 10 |
| HEMA | 6 | 2 | 2 | 1 | 10 | 4 | 2 | 4 |
| HEA | 0 | 0 | 0 | 0 | 0 | 0 | 0 | 0 |
| AIBN | 1 | 1 | 0.3 | 1 | 1 | 1 | 1 | 1 |
| nDM | 0 | 0 | 0 | 0 | 0 | 0 | 0 | 1.5 |
| Tg (° C.) of | −34 | −24 | −9 | −5 | −5 | −3 | −4 | −4 |
| acrylic polyol | | | | | | | | |
| Hydroxyl value | 25.9 | 8.6 | 8.6 | 4.3 | 43 | 17.2 | 8.6 | 17.2 |
| (mgKOH/g) | | | | | | | | |
| Weight average | 38,000 | 45,000 | 84,000 | 41,000 | 36,000 | 35,000 | 41,000 | 15,000 |
| molecular weight | | | | | | | | |
| Polymer | 1 | 2 | 3 | 4 | 5 | 6 | 7 | 8 |

TABLE 2

| | Synthetic Examples | | | | | | |
|---|---|---|---|---|---|---|---|
| | 9 | 10 | 11 | 12 | 13 | 14 | 15 |
| St | 3 | 2 | 0 | 0 | 3 | 0 | 3 |
| MMA | 28 | 3 | 0 | 35 | 26 | 0 | 30 |
| BA | 55 | 58 | 48 | 0 | 67 | 0 | 57 |
| EA | 0 | 0 | 0 | 57 | 0 | 0 | 0 |
| GMA | 2 | 0 | 0 | 0 | 0 | 0 | 0 |
| AN | 10 | 35 | 50 | 6 | 0 | 50 | 10 |
| HEMA | 0 | 2 | 2 | 2 | 4 | 50 | 0 |
| HEA | 2 | 0 | 0 | 0 | 0 | 0 | 0 |
| AIBN | 1 | 1 | 1 | 1 | 1 | 1 | 1 |
| nDM | 0 | 0 | 0 | 0 | 0 | 0 | 0 |
| Tg (° C.) of | −4 | −3 | 13 | 22 | −20 | 89 | −4 |
| acrylic polyol | | | | | | | |
| Hydroxyl value | 9.7 | 8.6 | 8.6 | 8.6 | 17.2 | 215 | 0 |
| (mgKOH/g) | | | | | | | |
| Weight average | 46,000 | 43,000 | 32,000 | 42,000 | 36,000 | 31,000 | 41,000 |
| molecular weight | | | | | | | |
| Polymer | 9 | 10 | 11 | 12 | 13 | 14 | 15 |

Calculation of glass transition temperature (Tg) of polymer Tgs of the polymers 1 to 15 were calculated by the above-mentioned formula (i) using the glass transition temperatures of homopolymers of the “polymerizable monomers” as a raw material of each polymer.

A document value was used as Tg of each homopolymer of methyl methacrylate and the like.

### Production of Adhesive for Solar Battery Back Sheet

Raw materials of adhesives for solar battery back sheets used in Examples and Comparative Examples are shown below.

### Acrylic Polyol(s)

The acrylic polyols correspond to the polymers 1 to 12 shown in Tables 1 and 2.

Acrylic polyol(s)′

The acrylic polyols' correspond to the polymers 13 and 14 shown in Table 2.

The acrylic polymer corresponds to the polymer 15 shown in Table 2.

### Isocyanate Compound

SUMIDULE N3300 (trade name) manufactured by Sumika Bayer Urethane Co., Ltd.: Aliphatic isocyanate (trimer of 1,6-diisocyanatohexane (HDI)).

A urethane resin is obtained by reacting an acrylic polyol with an isocyanate compound.

The below-mentioned adhesives for solar battery back sheets of Examples 1 to 12 and Comparative Examples 1 to 3 were produced using the above-mentioned components, and performances of the obtained adhesives for solar battery back sheets were evaluated. Production methods and evaluation methods are shown below.

### Example 1

### Production of Adhesive for Solar Battery Back Sheet

As shown in Table 3, 83.1 g of the polymer 1 [208 g of an ethyl acetate solution of the polymer 1 (solid content: 40.0% by weight)] and 16.9 g of SUMIDULE N3300 (trade name) manufactured by Sumika Bayer Urethane Co., Ltd. were weighed and then mixed to prepare an adhesive solution. Using this solution thus prepared as an adhesive for solar battery back sheets, the following tests were carried out. Production of adhesive-coated PET sheet 1 and film laminate 2

First, the adhesive for solar battery back sheets of Example 1 was applied to a transparent polyethylene terephthalate (PET) sheet (manufactured by Mitsubishi Polyester Film Corporation under the trade name of O300EW36) so that the weight of the solid component becomes 10 g/m², and then dried at 80° C. for 10 minutes to obtain an adhesive-coated PET sheet 1.

Then, a surface-treated transparent polyolefin film (linear low-density polyethylene film manufactured by Futamura Chemical Co., Ltd. under the trade name of LL-XUMN #30) was laid on the adhesive-coated surface of the adhesive-coated PET sheet 1 so that the surface-treated surface is brought into contact with the adhesive-coated surface, and then both films were pressed using a planar press machine (manufactured by SHINTO Metal Industries Corporation under the trade name of ASF-5) under a pressing pressure (or closing pressure) of 1.0 MPa at 50° C. for 30 minutes. While pressing, both films were cured at 40° C. for one day, and then cured at 60° C. for 3 days to obtain a film laminate 2.

### Evaluation

The adhesive for solar battery back sheets was evaluated by the following method. The evaluation results are shown in Table 3.

### 1. Evaluation of Initial Adhesion to Film

Under a room temperature environment, the adhesive-coated sheet 1 was cut out into pieces of 15 mm in width, and a surface-treated surface of a surface-treated transparent polyolefin film (linear low-density polyethylene film, manufactured by Futamura Chemical Co., Ltd. under the trade name of LL-XUMN #30) was laid on the adhesive-coated surface of the adhesive-coated sheet 1, and then both films are laminated each other by pressing using a 2 kg roller in a single reciprocal motion. Using a tensile strength testing machine (manufactured by ORIENTEC Co., Ltd. under the trade name of TENSILON®-250), a 180° peel test was carried out under a room temperature environment at a testing speed of 100 mm/min. The evaluation criteria are as shown below.

A: Peel strength is 1 N/15 mm or more

B: Peel strength is 0.5 N/15 mm or more and less than 1 N/15 mm

C: Peel strength is 0.1 N/15 mm or more and less than 0.5 N/15 mm

D: Peel strength is less than 0.1 N/15 mm

2. Measurement of the Initial Adhesive Property to Film after Curing

The film laminate 2 was cut into pieces of 15 mm in width, and then a 180° peel test was carried out under a room temperature environment at a testing speed of 100 ram/min, using the tensile strength testing machine (manufactured by ORIENTEC Co., Ltd. under the trade name of TENSILON®-250). The evaluation criteria are as shown below.

A: Peel strength is 10 N/15 mm or more

B: Peel strength is 6 N/15 mm or more and less than 10 N/15 mm

C: Peel strength is 1 N/15 mm or more and less than 6 N/15 mm

### 3. Evaluation of the Adhesive Property at a High Temperature

The film laminate 2 was cut into pieces of 15 mm in width and left to stand under an environment at 50° C. for 10 hours, and then a hand peel test was carried out under an environment at 50° C. The evaluation criteria are as shown below.

A: Material failure (or fracture) of polyolefin film occurred.

B: Peeling occurred with elongation of polyethylene film.

C: Peeling occurred with neither material failure nor elongation of polyolefin film.

### 4. Evaluation of the Hydrolysis Resistance

The evaluation was carried out by an accelerated evaluation method using pressurized steam. The film laminate 2 was cut into pieces of 15 mm in width, left to stand under a pressurizing environment at 121° C. under 0.1 MPa for 100 hours and 150 hours using a high-pressure cooker (manufactured by Yamato Scientific Co., Ltd. under the trade name of Autoclave SP300), and then aged under a room temperature environment for one day. Lifting and peeling of the polyolefin film and PET film of the sample were visually observed. The evaluation criteria are as follows.

A: Neither lifting nor peeling of film occurred after being left to stand for 150 hours.

B: Both lifting and peeling of film occurred within 100 to 150 hours.

D: Both lifting and peeling of film occurred within 100 hours.

### 5. Evaluation of the Solution Viscosity

Solution viscosity of each of Examples 1 to 12 and Comparative Examples 1 to 3 was measured at 20° C. and at a rotation number of 30 rpm, using a rotational viscometer (Model BM, manufactured by TOKIMEC Inc.) and spindle No. 3.

A: less than 500 mPa·s

B: 500 mPa·s or more and 3,000 mPa·s or less

C: 3,000 mPa·s or more

### Examples 2 to 12 and Comparative Examples 1 to 3

In the same manner as in Example 1, adhesives for solar battery back sheets were produced according to the compositions shown in Tables 3 and 4, and then evaluated. The evaluation results are shown in Tables 3 and 4.

TABLE 3

| | | Examples | | | | | | | |
|---|---|---|---|---|---|---|---|---|---|
| | | 1 | 2 | 3 | 4 | 5 | 6 | 7 | 8 |
| Acrylic polyol | Polymer 1 | 83.1 | | | | | | | |
| | Polymer 2 | | 95.1 | | | | | | |
| | Polymer 3 | | | 90.2 | | | | | |
| | Polymer 4 | | | | 97.6 | | | | |
| | Polymer 5 | | | | | 86.6 | | | |
| | Polymer 6 | | | | | | 95.1 | | |
| | Polymer 7 | | | | | | | 95.1 | |
| | Polymer 8 | | | | | | | | 93.2 |
| | Polymer 9 | | | | | | | | |
| | Polymer 10 | | | | | | | | |
| | Polymer 11 | | | | | | | | |
| | Polymer 12 | | | | | | | | |
| Acrylic polyol′ | Polymer 13 | | | | | | | | |
| | Polymer 14 | | | | | | | | |
| Acrylic polymer | Polymer 15 | | | | | | | | |

| | | | | | | | | |
|---|---|---|---|---|---|---|---|---|
| Isocyanate compound | 16.9 | 4.9 | 9.8 | 2.4 | 13.4 | 4.9 | 4.9 | 6.8 |
| Initial adhesion | A | A | A | A | A | A | A | A |
| Initial adhesive property | B | A | A | A | B | B | A | A |
| after curing | | | | | | | | |
| Adhesive property | B | B | A | B | A | B | A | B |
| at high temperature | | | | | | | | |
| Hydrolysis resistance | A | A | A | B | B | A | A | B |
| Solution viscosity | A | A | A | A | A | A | A | A |

TABLE 4

| | | Examples | | | | Comparative Examples | | |
|---|---|---|---|---|---|---|---|---|
| | | 9 | 10 | 11 | 12 | 1 | 2 | 3 |
| Acrylic polyol | Polymer 1 | | | | | | | |
| | Polymer 2 | | | | | | | |
| | Polymer 3 | | | | | | | |
| | Polymer 4 | | | | | | | |
| | Polymer 5 | | | | | | | |
| | Polymer 6 | | | | | | | |
| | Polymer 7 | | | | | | | |
| | Polymer 8 | | | | | | | |
| | Polymer 9 | 90.2 | | | | | | |
| | Polymer 10 | | 95.8 | | | | | |
| | Polymer 11 | | | 95.1 | | | | |
| | Polymer 12 | | | | 95.1 | | | |
| Acrylic polyol′ | Polymer 13 | | | | | 93.2 | | |
| | Polymer 14 | | | | | | 77.9 | |
| Acrylic polymer | Polymer 15 | | | | | | | 95.1 |

| | | | | | | | |
|---|---|---|---|---|---|---|---|
| Isocyanate compound | 9.8 | 4.2 | 4.9 | 4.9 | 6.8 | 27.1 | 4.9 |
| Initial adhesion | A | A | B | C | A | D | A |
| Initial adhesive property | A | A | A | B | C | A | C |
| after curing | | | | | | | |
| Adhesive property | A | A | A | A | D | A | D |
| at high temperature | | | | | | | |
| Hydrolysis resistance | A | A | A | A | A | D | D |
| Solution viscosity | A | B | C | A | A | C | A |

As shown in Tables 1 to 4, since the adhesives for solar battery back sheets of Examples 1 to 12 contain a urethane resin obtainable by the reaction of an acrylic polyol with an isocyanate compound, and are obtainable by polymerizing a hydroxyalkyl (meth)acrylate with monomers including acrylonitrile and a (meth)acrylic ester as the polymerizable monomers for synthesizing the acrylic polyol, the obtained adhesives are excellent in initial adhesion to a film at the time of coating, initial adhesive property after curing and adhesive property at high temperature, and are also excellent in hydrolysis resistance and has satisfactory total balance. Therefore, the adhesives of Examples are suited for use as an adhesive for solar battery back sheets.

Particularly, the adhesives for solar battery back sheets of Examples 3, 7 and 9 have a viscosity suited for coating and are excellent in all of initial adhesion to a film at the time of coating, an initial adhesive property after curing, an adhesive property at high temperature and hydrolysis resistance, and thus they are most suited for use as an adhesive for back sheets of a solar battery.

To the contrary, the adhesive of Comparative Example 1 has not sufficient initial adhesive property to a film after curing and is inferior in adhesive property at high temperature since the polymerizable monomers contain no acrylonitrile.

The adhesive of Comparative Example 2 is inferior in initial adhesion to a film and hydrolysis resistance, since the polymerizable monomers contain no (meth)acrylic ester.

The adhesive of Comparative Example 3 is inferior in adhesive property at high temperature and hydrolysis resistance, since the polymerizable monomers do not contain a monomer having a hydroxyl group.

These results revealed that it is possible to obtain a urethane adhesive which is suited for use in a solar battery back sheets when polymerizable monomers as raw materials of an acrylic polyol contain a hydroxyalkyl (meth)acrylate, acrylonitrile and (meth)acrylic ester(s).

### INDUSTRIAL APPLICABILITY

The present invention provides an adhesive for solar battery back sheets. The adhesive for solar battery back sheets according to the present invention is excellent in productivity and has high adhesive property to a backsheet film and long-term durability, and can be suitably used in a solar battery back sheet and a solar battery module.

### DESCRIPTION OF REFERENCE NUMERALS

1: Solar battery module, 10: Back sheet, 11: Film 11a: Deposited thin film, 12: Film, 13: Adhesive layer 20: Sealing material (EVA), 30: Solar battery cell 40: Glass plate, 50: Spacer

What is claimed is:

1. An adhesive for solar battery back sheets, comprising a urethane resin obtainable by the reaction of an acrylic polyol with an isocyanate compound, wherein
the acrylic polyol is obtainable by polymerizing polymerizable monomers,
the polymerizable monomers comprise a monomer having a hydroxyl group and other monomers,
the monomer having a hydroxyl group comprises a hydroxyalkyl (meth)acrylate, and
the other monomers comprise acrylonitrile and (meth)acrylic ester(s).

2. The adhesive for solar battery back sheets according to claim 1, wherein the content of the acrylonitrile is 1 to 40 parts by weight based on 100 parts by weight of the polymerizable monomers.

3. The adhesive for solar battery back sheets according to claim 1, wherein the acrylic polyol has a glass transition temperature of 20° C. or lower.

4. The adhesive for solar battery back sheets according to claim 1, wherein the acrylic polyol has a hydroxyl value of 0.5 to 45 mgKOH/g.

5. A solar battery back sheet comprising the adhesive for solar battery back sheets according to claim 1.

6. A solar battery module comprising the solar battery back sheet according to claim 5.

7. A solar battery back sheet comprising cured reaction products of the adhesives according to claim 1.

8. A solar battery module comprising cured reaction products of the adhesives according to claim 1.
